(19) United States
(12) Patent Application Publication
(10) Pub. No.: US 2025/0138491 A1
(43) Pub. Date: May 1, 2025

(54) TECHNOLOGIES FOR LOW POWER INDOOR AND OUTDOOR DETECTION

(71) Applicant: Intel Corporation, Santa Clara, CA (US)

(72) Inventors: Shouwei Sun, Shanghai (CN); Hemin Han, Shanghai (CN); Lili Ma, Shanghai (CN); Ke Han, Minhang District (CN); Rahul C. Shah, San Francisco, CA (US); Lu Wang, Shanghai (CN)

(73) Assignee: Intel Corporation, Santa Clara, CA (US)

(21) Appl. No.: 18/838,740

(22) PCT Filed: Apr. 2, 2022
(86) PCT No.: PCT/CN2022/084971

§ 371 Date: Aug. 15, 2024

(51) Int. Cl. G05B 13/02; G01J 1/42; G01P 15/00; G01R 33/00

(52) U.S. Cl. CPC G05B 13/027; G01J 1/4204; G01P 15/00; G01R 33/0023

(57) ABSTRACT

Techniques for low power indoor/outdoor detection are disclosed. In the illustrative embodiment, an integrated sensor hub receives data from an accelerometer. The sensor hub processes the accelerometer data to determine an activity of the user. Depending on the activity of the user, the sensor hub may determine whether the compute device is indoors or outdoors or may receive data from additional sensors, such as a magnetometer, a gyroscope, or an ambient light sensor. The additional sensor data may be used to determine whether the compute device is inside or outside.

### BACKGROUND

Laptops and other mobile devices are ubiquitous in modern life. As a result of their mobility, laptops and other mobile devices may move between indoor and outdoor environments. Depending on whether the compute device is indoors or outdoors, it may change its behavior. For example, use of certain wireless channels outdoors may be regulated differently than use of wireless channels indoors.

### BRIEF DESCRIPTION OF THE DRAWINGS

FIG. 1 is a simplified block diagram of at least one embodiment of a compute device for indoor/outdoor detection.

FIG. 2 is a simplified block diagram of at least one embodiment of an environment that may be established by the compute device of FIG. 1.

FIG. 3 is a simplified diagram showing a user of a mobile device in a deep indoor environment.

FIG. 4 is a simplified diagram showing a user of a mobile device in a light indoor environment.

FIG. 5 is a simplified diagram showing a user of a mobile device in a semi- outdoor environment.

FIG. 6 is a simplified diagram showing a user of a mobile device in an open outdoor environment.

FIG. 7 is a plot showing one embodiment of accelerometer data corresponding to a user of a mobile compute device walking.

FIG. 8 is a plot showing one embodiment of accelerometer data corresponding to a user of a mobile compute device being sedentary.

FIG. 9 is a plot showing one embodiment of accelerometer data corresponding to a user of a mobile compute device fidgeting.

FIG. 10 is a plot showing one embodiment of accelerometer data corresponding to a user of a mobile compute device running.

FIG. 11 is a plot showing one embodiment of accelerometer data corresponding to a user of a mobile compute device in a vehicle.

FIG. 12 is a plot showing one embodiment of accelerometer data corresponding to a user of a mobile compute device biking.

FIG. 13 is a plot showing one embodiment of transitions between states of the compute device of FIG. 1.

FIGS. 14-16 are a simplified flow diagram of at least one embodiment of a method for indoor/outdoor detection that may be executed by the compute device of FIG. 1.

### DETAILED DESCRIPTION

A mobile device such as a laptop or cell phone can benefit from determining its environment, such as determining whether the compute device is indoors or outdoors. For example, the Federal Communications Commission (FCC) and other regulatory agencies may restrict use of certain wireless channels outdoors and permit use of those channels indoors. For example, in the United States, fewer channels are available for use outdoors at 5 gigahertz compared to indoors. Accurately detecting whether a device is indoors or outdoors with low power can improve user experience and increase battery life. However, some approaches for determining whether a device is indoors or outdoors rely on using GPS or other satellite navigation data, which requires use of a relatively high-power circuit.

In order to determine whether a device is indoors or outdoors, in the illustrative embodiment, accelerometer data can be used to determine an activity of the user. Depending on the determined activity, whether the compute device is indoors or outdoors can be determined. If necessary, additional sensor data such as data from a magnetometer, ambient light sensor, and/or a gyroscope can be used to determine whether the compute device is indoors or outdoors.

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

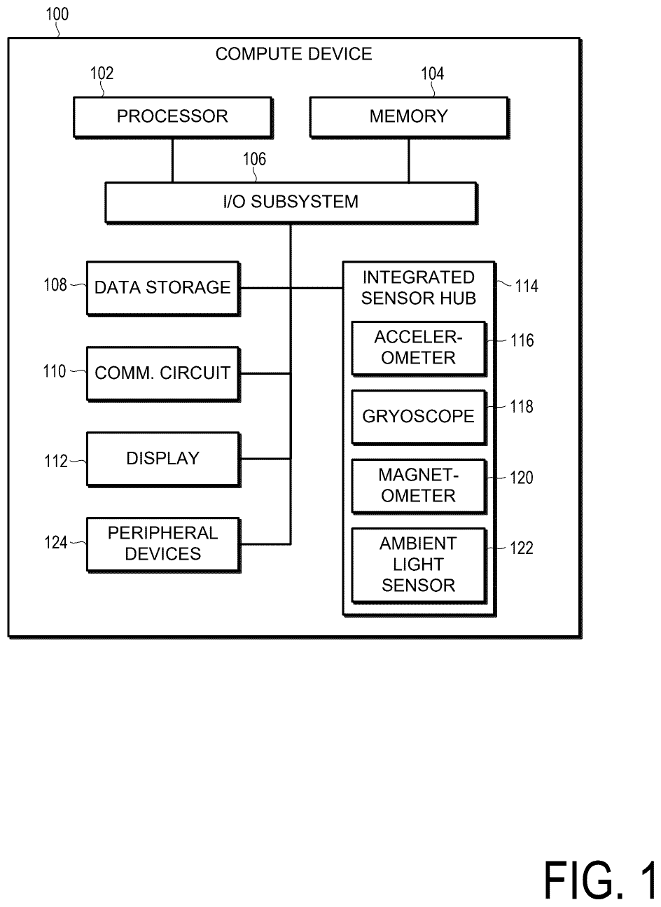

Referring now to FIG. 1, in one embodiment, a compute device 100 for determining whether the compute device is indoors or outdoors is disclosed. The compute device 100 may be embodied as any type of compute device. For example, the compute device 100 may be embodied as or otherwise be included in, without limitation, a laptop computer, a smartphone, a consumer electronic device, a cellular phone, a server computer, an embedded computing system, a System-on-a-Chip (SoC), a multiprocessor system, a processor-based system, a desktop computer, a tablet computer, a notebook computer, a network device, a router, a switch, a networked computer, a wearable computer, a handset, a messaging device, a camera device, and/or any other compute device. The compute device 100 may have any suitable form factor, such as a cell phone, a clamshell laptop, a detachable laptop, a 2-in-1 laptop/tablet, a desktop tower, a blade in a server, a system-on-a-chip, etc. In some embodiments, the compute device 100 may be located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

The illustrative compute device 100 includes a processor 102, a memory 104, an input/output (I/O) subsystem 106, data storage 108, a communication circuit 110, a display 112, an integrated sensor hub 114, and one or more peripheral devices 124. In some embodiments, one or more of the illustrative components of the compute device 100 may be incorporated in, or otherwise form a portion of, another component. For example, the memory 104, or portions thereof, may be incorporated in the processor 102 in some embodiments. In some embodiments, one or more of the illustrative components may be physically separated from another component.

The processor 102 may be embodied as any type of processor capable of performing the functions described herein. For example, the processor 102 may be embodied as a single or multi-core processor(s), a single or multi-socket processor, a digital signal processor, a graphics processor, a neural network compute engine, an image processor, a microcontroller, or other processor or processing/controlling circuit. Similarly, the memory 104 may be embodied as any type of volatile or non-volatile memory or data storage capable of performing the functions described herein. In operation, the memory 104 may store various data and software used during operation of the compute device 100 such as operating systems, applications, programs, libraries, and drivers. The memory 104 is communicatively coupled to the processor 102 via the I/O subsystem 106, which may be embodied as circuitry and/or components to facilitate input/output operations with the processor 102, the memory 104, and other components of the compute device 100. For example, the I/O subsystem 106 may be embodied as, or otherwise include, memory controller hubs, input/output control hubs, firmware devices, communication links (i.e., point-to-point links, bus links, wires, cables, light guides, printed circuit board traces, etc.) and/or other components and subsystems to facilitate the input/output operations. The I/O subsystem 106 may connect various internal and external components of the compute device 100 to each other with use of any suitable connector, interconnect, bus, protocol, etc., such as an SoC fabric, PCIe®, USB2, USB3, USB4, NVMe®, Thunderbolt®, and/or the like. In some embodiments, the I/O subsystem 106 may form a portion of a system-on-a-chip (SoC) and be incorporated, along with the processor 102, the memory 104, and other components of the compute device 100 on a single integrated circuit chip.

The data storage 108 may be embodied as any type of device or devices configured for the short-term or long-term storage of data. For example, the data storage 108 may include any one or more memory devices and circuits, memory cards, hard disk drives, solid-state drives, or other data storage devices.

The communication circuit 110 may be embodied as any type of interface capable of interfacing the compute device 100 with other compute devices, such as over one or more wired or wireless connections. In some embodiments, the communication circuit 110 may be capable of interfacing with any appropriate cable type, such as an electrical cable or an optical cable. The communication circuit 110 may be configured to use any one or more communication technology and associated protocols (e.g., Ethernet, Bluetooth®, Wi-Fi®, WiMAX, near field communication (NFC), etc.). The communication circuit 110 may be located on silicon separate from the processor 102, or the communication circuit 110 may be included in a multi-chip package with the processor 102, or even on the same die as the processor 102. The communication circuit 110 may be embodied as one or more add-in-boards, daughtercards, network interface cards, controller chips, chipsets, specialized components such as a field-programmable gate array (FPGA) or application-specific integrated circuit (ASIC), or other devices that may be used by the compute device 102 to connect with another compute device. In some embodiments, communication circuit 110 may be embodied as part of a system-on-a-chip (SoC) that includes one or more processors or included on a multichip package that also contains one or more processors. In some embodiments, the communication circuit 110 may include a local processor (not shown) and/or a local memory (not shown) that are both local to the communication circuit 110. In such embodiments, the local processor of the communication circuit 110 may be capable of performing one or more of the functions of the processor 102 described herein. Additionally or alternatively, in such embodiments, the local memory of the communication circuit 110 may be integrated into one or more components of the compute device 102 at the board level, socket level, chip level, and/or other levels.

The display 112 may be embodied as any type of display on which information may be displayed to a user of the compute device 100, such as a touchscreen display, a liquid crystal display (LCD), a thin film transistor LCD (TFT-LCD), a light-emitting diode (LED) display, an organic light-emitting diode (OLED) display, a cathode ray tube (CRT) display, a plasma display, an image projector (e.g., 2D or 3D), a laser projector, a heads-up display, and/or other display technology. The display 112 may have any suitable resolution, such as 7680×4320, 3840×2160, 1920×1200, 1920×1080, etc.

The integrated sensor hub 114 is a hub that can interface and process data from several sensors. The integrated sensor hub 114 may be configured to process data from several sensors in a particular manner while using low power. The integrated sensor hub 114 may include a general and/or application specific processor and memory, which may be similar to the processor 102 and memory 104 but with less computing power and less energy requirements. The integrated sensor hub 114 can communicate results from processing data to the processor 102, memory 104, or other component of the compute device 102. In the illustrative embodiment, the integrated sensor hub 114 includes with an accelerometer 116, a gyroscope 118, a magnetometer 120, and an ambient light sensor 122. In other embodiments, the integrated sensor hub 114 may receive data from the accelerometer 116, gyroscope 118, magnetometer 120, and ambient light sensor 122 without some or all of the sensors 116, 118, 120, 122 forming part of the integrated sensor hub 114. In the illustrative embodiment, the integrated sensor hub 114 performs some or all of the processing of data from the sensors 116, 118, 120, 122 in order to determine whether the compute device 100 is indoors or outdoors. In other embodiments, other components of the compute device 100 such as the processor 102 may perform some or all of the processing of data from the sensors 116, 118, 120, 122 in order to determine whether the compute device 100 is indoors or outdoors.

The illustrative accelerometer 116 is configured to sense acceleration in one, two, or three directions and provide acceleration data to the integrated sensor hub 114. The illustrative gyroscope 118 is configured to sense rotation and/or orientation in one, two, or three directions and provide rotation and/or orientation data to the integrated sensor hub 114. The illustrative magnetometer is configured to sense a magnetic field in one, two, or three directions and provide magnetic field data to the integrated sensor hub 114. The illustrative ambient light sensor 122 is configured to sense ambient light and provide ambient light data to the integrated sensor hub 114. The ambient light sensor 122 may be, e.g., a one-pixel or multi-pixel camera. The various sensors of the integrated sensor hub 114 may use any suitable amount of power. For example, in one embodiment, the ambient light sensor 122 may use about two milliwatts, the gyroscope 118 may use about 0.8 milliwatts, the magnetometer 120 may use about 0.3 milliwatts, and the accelerometer 116 may use about 0.05 milliwatts. In one embodiment, the sensor hub 114 may use less than 5 milliwatts average power to determine the indoor/outdoor state of the compute device 100, including the power used by the various sensors. In other embodiment, the sensor hub 114 may, e.g., 3-30 milliwatts of average power to determine the indoor/outdoor state of the compute device 100, including the power used by the various sensors

In some embodiments, the compute device 100 may include other or additional components, such as those commonly found in a compute device. For example, the compute device 100 may also have peripheral devices 124, such as a keyboard, a mouse, a speaker, a camera, a microphone, an external storage device, a battery, etc. In some embodiments, the compute device 100 may be connected to a dock that can interface with various devices, including peripheral devices 124.

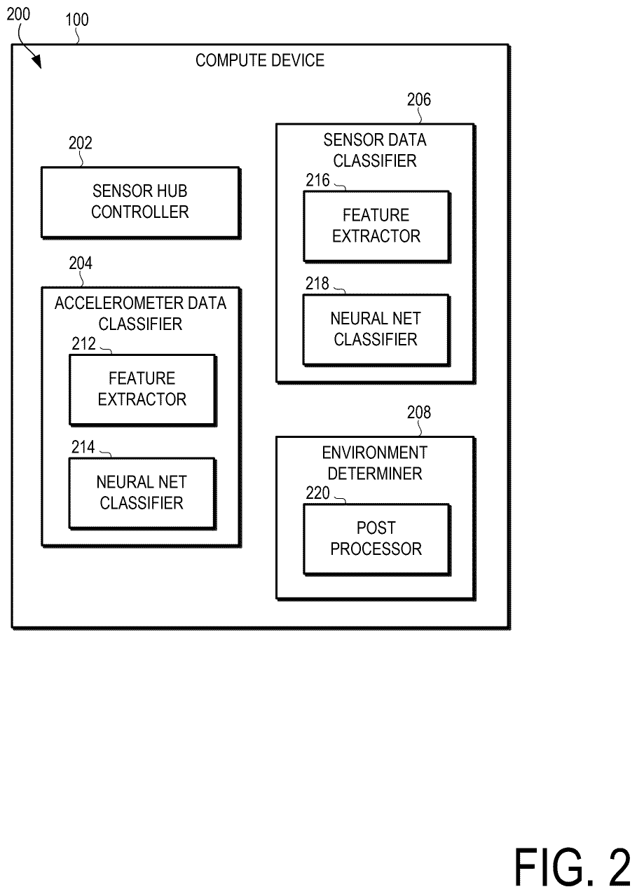

Referring now to FIG. 2, in an illustrative embodiment, the compute device 100 establishes an environment 200 during operation. The illustrative environment 200 includes sensor hub controller 202, accelerometer data classifier 204, sensor data classifier 206, environment determiner 208, and communication circuitry 210. The various modules of the environment 200 may be embodied as hardware, software, firmware, or a combination thereof. For example, the various modules, logic, and other components of the environment 200 may form a portion of, or otherwise be established by, the processor 102, the memory 104, the data storage 108, or other hardware components of the compute device 100. As such, in some embodiments, one or more of the modules of the environment 200 may be embodied as circuitry or collection of electrical devices (e.g., sensor hub controller circuitry 202, accelerometer data classifier circuitry 204, sensor data classifier circuitry 206, etc.). It should be appreciated that, in such embodiments, one or more of the circuits (e.g., the sensor hub controller circuitry 202, the accelerometer data classifier circuitry 204, the sensor data classifier circuitry 206, etc.) may form a portion of one or more of the processor 102, the memory 104, the I/O subsystem 106, the data storage 108, and/or other components of the compute device 100. For example, in some embodiments, some or all of the modules may be embodied as the processor 102 as well as the memory 104 and/or data storage 108 storing instructions to be executed by the processor 102. Additionally, in some embodiments, one or more of the illustrative modules may form a portion of another module and/or one or more of the illustrative modules may be independent of one another. Further, in some embodiments, one or more of the modules of the environment 200 may be embodied as virtualized hardware components or emulated architecture, which may be established and maintained by the processor 102 or other components of the compute device 100. It should be appreciated that some of the functionality of one or more of the modules of the environment 200 may require a hardware implementation, in which case embodiments of modules that implement such functionality will be embodied at least partially as hardware.

The sensor hub controller 202, which may be embodied as hardware, firmware, software, virtualized hardware, emulated architecture, and/or a combination thereof, as discussed above, is configured to interface with and receive sensor data from, e.g., the accelerometer 116, the gyroscope 118, the magnetometer 120, and ambient light sensor 122.

The accelerometer data classifier 204, which may be embodied as hardware, firmware, software, virtualized hardware, emulated architecture, and/or a combination thereof, as discussed above, is configured to process and classify accelerometer data. In the illustrative embodiment, the accelerometer data classifier 204 may classify one or more frames of accelerometer data at a time, with each frame corresponding to data received at a rate of 50Hertz for about 5 seconds. The accelerometer data classifier 204 may receive, e.g., 1-10 frames for feature extraction and classification. In other embodiments, the accelerometer data classifier 204 may receive accelerometer data at any suitable rate, such as 10-200 Hz, and for any suitable length of time, such as 1-20 seconds.

The accelerometer data classifier 204 may use a feature extractor 212 to perform feature extraction on the accelerometer data. In the illustrative embodiment, the feature extractor 212 uses 20 sub-band energy features and 20 evenly spaced frequency bands over the spectrum, for a total of 41 features. In other embodiments, the feature extractor 212 may perform feature extraction in a different manner, such as extracting a different number of features, a different number of frequency bands, etc.

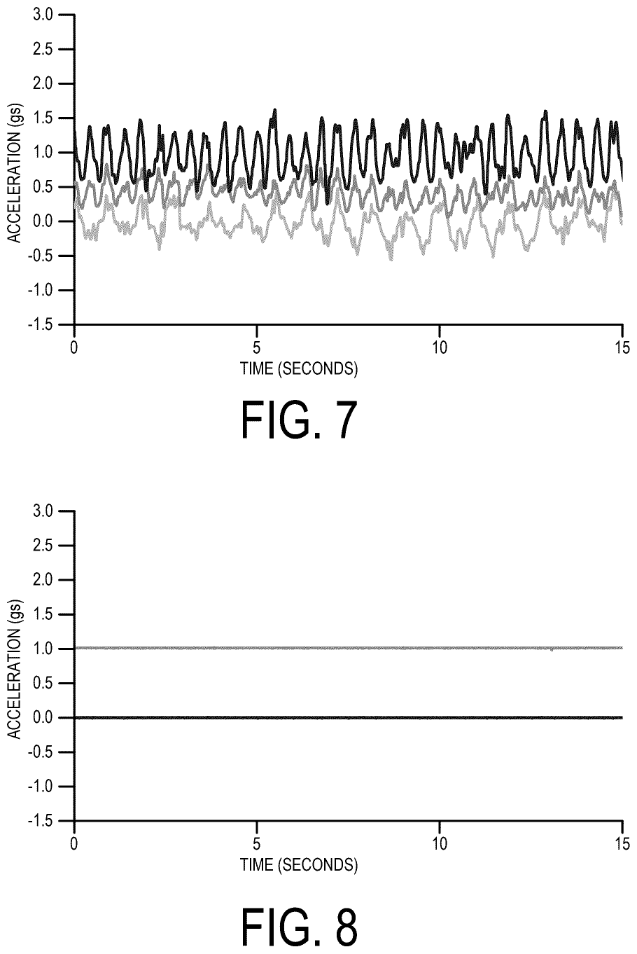

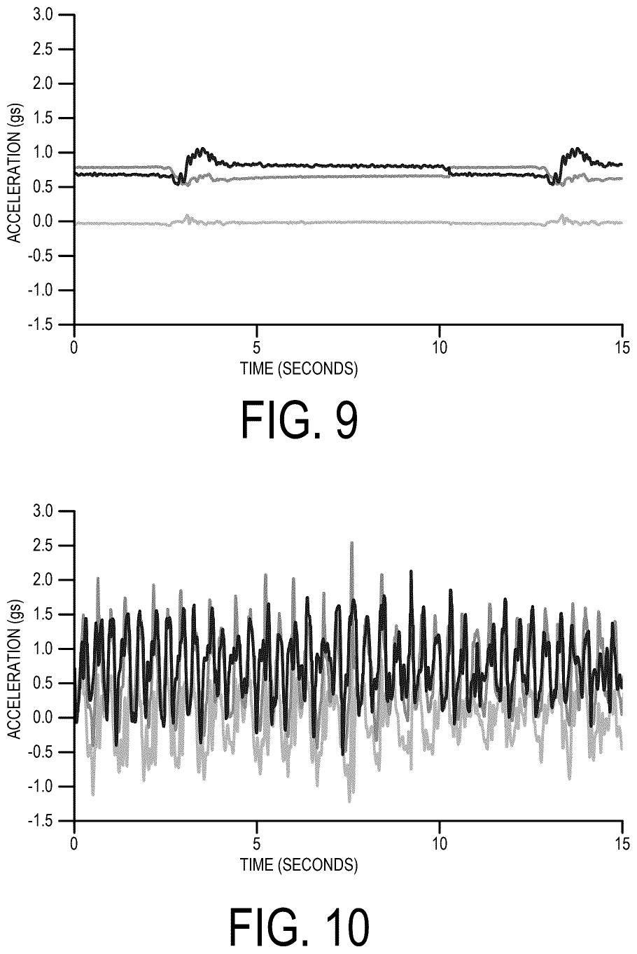

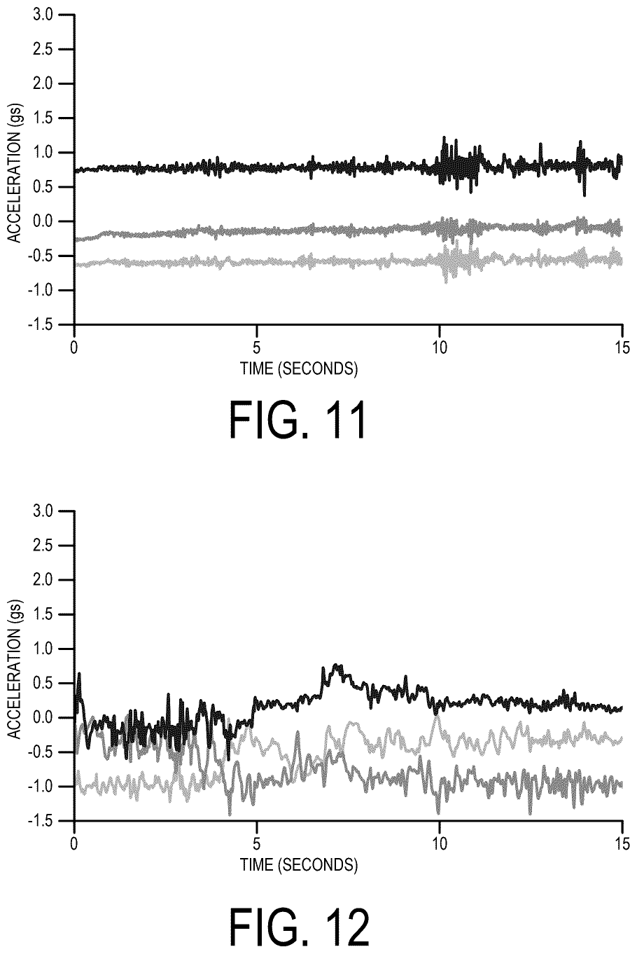

Examples of accelerometer data are shown in FIGS. 7-12. In FIG. 7, accelerometer data is shown for a user of a compute device 100 that is walking. In FIG. 8, accelerometer data is shown for a user of a compute device 100 that is sedentary. In FIG. 9, accelerometer data is shown for a user of a compute device 100 that is fidgeting. In FIG. 10, accelerometer data is shown for a user of a compute device 100 that is running. In FIG. 11, accelerometer data is shown for a user of a compute device 100 that is in a vehicle. In FIG. 12, accelerometer data is shown for a user of a compute device 100 that is biking. The three lines in each plot show acceleration in the x, y, and z direction.

The accelerometer data classifier 204 uses a neural net classifier 214 to classify the accelerometer data based on the extracted features. In the illustrative embodiment, the neural net classifier 214 classifies the accelerometer data into one of several possible user activities. In the illustrative embodiment, the activities are walking, being sedentary, being in a vehicle, running, biking, fidgeting, and unknown. The illustrative neural net classifier 214 determines an activity of the user based on the features identified. In some embodiments, sensor data from a sensor different from the accelerometer 116 may be used to determine an activity of the user of the compute device 100. Additionally or alternatively, in other embodiments, a different classifier may be used, such as another machine-learning-based or non-machine learning-based classifier.

The sensor data classifier 206, which may be embodied as hardware, firmware, software, virtualized hardware, emulated architecture, and/or a combination thereof, as discussed above, is configured to receive additional sensor data, such as magnetometer data from the magnetometer 120, ambient light data from the ambient light sensor 122, and/or gyroscope data from the gyroscope 118. In the illustrative embodiment, the magnetometer 120, ambient light sensor 122, and/or the gyroscope 118 may not be powered on until the sensor data classifier 206 determines that it needs to receive data from the corresponding sensor. In some embodiments, the sensor data classifier 206 may not receive data from all of the magnetometer 120, the ambient light sensor 122, and the gyroscope 118.

The sensor data classifier 206 may receive any suitable amount of sensor data at any suitable rate. In the illustrative embodiment, the sensor data classifier 206 receives one or more frames of sensor data from magnetometer 120, gyroscope 118, and ambient light sensor 122 data, with each frame corresponding to data received at a rate of 10 Hertz for about 5 seconds. The sensor data classifier 206 may receive, e.g., 1-10 frames for feature extraction and classification. In other embodiments, the sensor data classifier 206 may receive sensor data from any suitable sensor at any suitable rate, such as 1-200 Hz, and for any suitable length of time, such as 1-20 seconds.

The sensor data classifier 206 includes a feature extractor 216 to perform feature extraction on the sensor data received by the sensor data classifier 206. Magnetometer data may reflect the effect that metallic objects or electrical appliances have on the Earth's magnetic field, which can be used as fingerprints for indoor detection compared to open spaces outdoors. As the sunlight is the primary source of light in the daytime and the light intensity is typically much higher outdoor than indoor, even on cloudy or rainy days, the ambient light data can be used to help determine whether the compute device 100 is outdoors or indoors. Gyroscope data may be used to help determine whether the compute device 100 is indoors or outdoors as the rotation angle of the compute device 100 may be different indoors and outdoors. For example, a laptop may be held in a hand indoor and placed in a bag outdoors.

In some embodiments, the feature extractor 216 may use features extracted from the accelerometer data. The features may be used to represent activities besides the six identified above, such as skipping, jogging, going up or down stairs, etc. For example, jogging is likely to be in an open outdoor or semi-outdoor environment, and going up or down stairs is likely to happen in a semi-outdoor or light indoor environment. The accelerometer data may be that received by the accelerometer data classifier 204 or may be received at the same time as the rest of the sensor data by the sensor data classifier 206.

In the illustrative embodiment, the feature extractor 216 extracts time domain and/or frequency features from the sensor data. The features from different sensors may be concatenated into one feature vector per frame. The time domain features may include mean, standard deviation, media, quantiles, range, and mean crossing rate. The frequency domain features may include dominant frequency, spectrum entropy, spectrum roll-off, and 20 sub-band energies. The magnetometer and gyroscope, in some embodiments, the magnitude of the field in computed from a 3-dimensional input, and features are extracted from magnitude only. In other embodiments, features may be extracted using all three dimensions. In the illustrative embodiment, frequency analysis may not be performed on the ambient light data, as the ambient light data does not change as fast as that of the magnetometer and gyroscope. Time domain features extracted from the ambient light sensor may include mean, median, kurtosis (Fisher or Pearson), and range. In total, in the illustrative embodiment, 121 features (including 41 activity features) are extracted per frame.

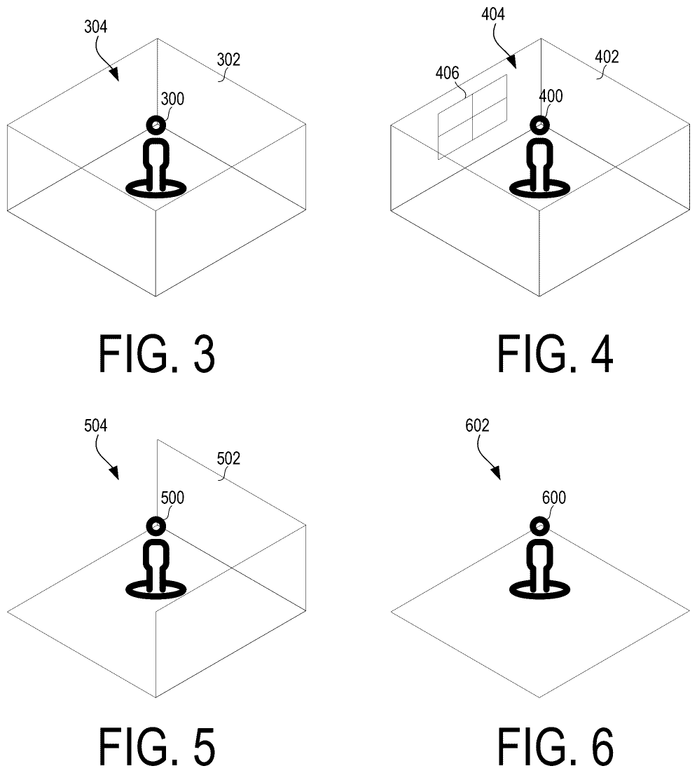

The sensor data classifier 206 includes a neural net classifier 218 that classifies the sensor data. In the illustrative embodiment, the neural net classifier 218 classifies the sensor data into one of several possible user environments for the compute device 100. In particular, in the illustrative embodiment, the compute device 100 may classify the sensor data into a deep indoor environment, a light indoor environment, a semi-outdoor environment, and an open outdoor environment. An example embodiment of a deep indoor environment 304 is shown in FIG. 3, in which a user 300 of the compute device 100 may be in, e.g., a room with four walls 302. An example embodiment of a light indoor environment 404 is shown in FIG. 4, in which a user 400 of the compute device 100 may be in, e.g., a room with several walls 402 and one or more large windows 406. An example embodiment of a semi-outdoor environment 504 is shown in FIG. 5, in which a user 500 of the compute device 100 may be, e.g., near a building 502. An example embodiment of an open outdoor environment 602 is shown in FIG. 6, in which a user 600 of the compute device 100 may be outside with no buildings nearby.

In the illustrative embodiment, the neural net classifier 218 uses a neural network classifier to determine an environment of the compute device 100. The illustrative neural network is a deep neural network with a 4-layer feed forward network with 57 neurons in the first hidden layer and 30 neurons in the second hidden layer. An input layer has 121 neurons, and the output layer has four classes. A rectified linear unit (ReLU) is used as an activation function. The illustrative DNN uses L2 regularization and a drop layout right before the final output layer. The DNN is trained with an Adam optimizer for 60 iterations with early stopping.

In the illustrative embodiment, the neural net classifier 218 is trained using labeled training data. In one example, two evaluations methods were used to train and evaluate the neural net classifier 218. For one method, which used five-fold cross validation, a label training data sample is randomly partitioned into five equal size subsamples. One subsample is retained as the validation data for testing the model, and the remaining four subsamples are used as training data. In one example, the precision and F1-score for deep indoor was 0.9533 and 0.965. The precision and F1-score for light indoor was 0.8638 and 0.7986, respectively. The precision and F1-score for semi-outdoor was 0.9102 and 0.8893, respectively. The precision and F1-score for open outdoor was 0.9969 and 0.9972, respectively.

For another method, which used manual split, eight days of data in different scenes and different daytimes was recorded. Two days were selected as verification data. The precision and F1-score for deep indoor was 0.9558 and 0.9608. The precision and F1-score for light indoor was 0.4186 and 0.3273, respectively. The precision and F1-score for semi-outdoor was 0.8597 and 0.862, respectively. The precision and F1-score for open outdoor was 0.9904 and 0.9916, respectively.

The environment determiner 208, which may be embodied as hardware, firmware, software, virtualized hardware, emulated architecture, and/or a combination thereof, as discussed above, is configured to determine an environment of the compute device 100. In the illustrative embodiment, the environment determiner 208 uses the accelerometer data classifier 204 to identify the activity of the user. If the identified activity of the user is being sedentary, then the environment determiner 208 determines that the current environment of the compute device 100 based on the previous result. For example, if the environment determiner 208 had determined that the compute device 100 was inside immediately before receiving and processing the accelerometer data, the environment determiner 208 may determine that it is still inside. In the illustrative embodiment, the environment determiner 208 environment monitoring is “always on,” continuously monitoring whether it is indoors or outdoors, so the previous result was determined relatively recently.

If the identified activity of the user is biking or being in a vehicle, then the environment determiner 208 determines that the current environment is an open outdoor environment. If the identified activity of the user is walking or running, then the environment determiner 208 uses the sensor data classifier 206 to classify sensor data from various sensors, such as the accelerometer 116, magnetometer 120, ambient light sensor 122, and/or gyroscope 118. If the identified activity of the user is fidgeting or unknown, the environment determiner 208 may use the accelerometer data classifier 204 to classify another frame of accelerometer data or may use the sensor data classifier 206 to classify the environment with data from additional sensors.

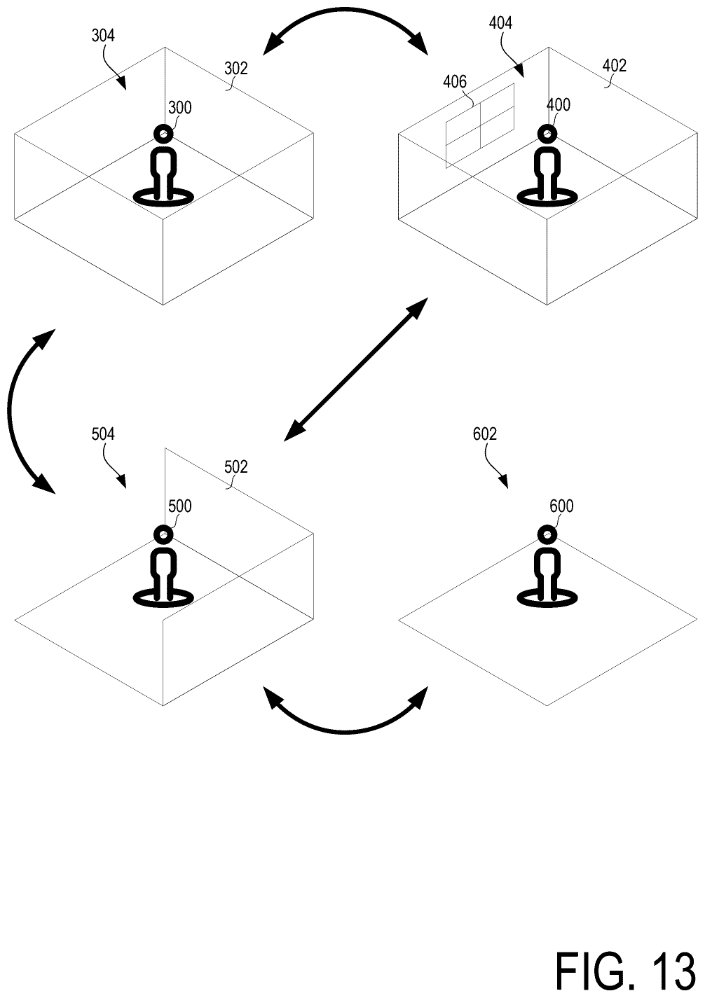

After the environment is preliminarily identified based on the accelerometer data classifier 204 and/or the sensor data classifier 206, the environment determiner 208 uses a post processor 220 to apply post-processing. The post processor 220 may apply an historical filter, which can help filter out disturbances and improve accuracy. The historical filter can also use switch rules to improve the performance of the indoor/outdoor detection, as shown in FIG. 13. For example, FIG. 13 shows one embodiment of allowable transitions between states. As shown in FIG. 13, the algorithm cannot directly switch from open outdoor 602 to deep indoor 304 (or vice-versa). In some embodiments, the post processor 220 may determine a confidence level. For example, if all of the previous, e.g., 10 estimates of the state of the environment are the same, the compute device 100 may have a high confidence. If, for example, the past 10 estimates of the state of the environment have been alternating between light indoor and semi-outdoor, the post processor 220 may have a low confidence.

After determining an environment, the environment determiner 208 may take action based on the determination of whether the compute device 100 is in an indoor environment or an outdoor environment. For example, if the compute device 100 is outdoors (i.e., semi-outdoors or open outdoors), the environment determiner 208 may change a wireless scanning procedure. The compute device 100 may not need to scan channels that cannot be used outside while the compute device 100 is outside, and the environment determiner 208 may disable transmission on those channels. Conversely, if the compute device 100 is inside (i.e., light inside or deep inside), the compute device 100 may scan all usable channels. Additionally or alternatively, the environment determiner 208 may change a mode of a camera based on a determination of whether the compute device 100 is inside and/or may change a mode of a microphone based on a determination of whether the compute device 100 is inside. In some embodiments, the compute device 100 may use the indoor/outdoor environment determination for upper layer applications such as, e.g., healthcare monitoring, tourism, or advertising to recommend personalized products.

It should be appreciated that, in the illustrative embodiment, only accelerometer data is needed for the environment determiner 208, unless the user is walking or running or performing an unknown activity. As such, the environment determiner 208 can determine its environment without needing to power on other sensors. It should further be appreciated that, in the illustrative embodiment, the environment determiner 208 can continuously determine the indoor/outdoor environment of the compute device 100 without use of high-power circuits such as cellular, Wi-Fi, or GPS or other satellite positioning data. As used herein, satellite positioning data refers to positioning data received from one or more satellites, such as Global Positioning System (GPS), Global Navigation Satellite Systems (GLONASS), and/or the like.

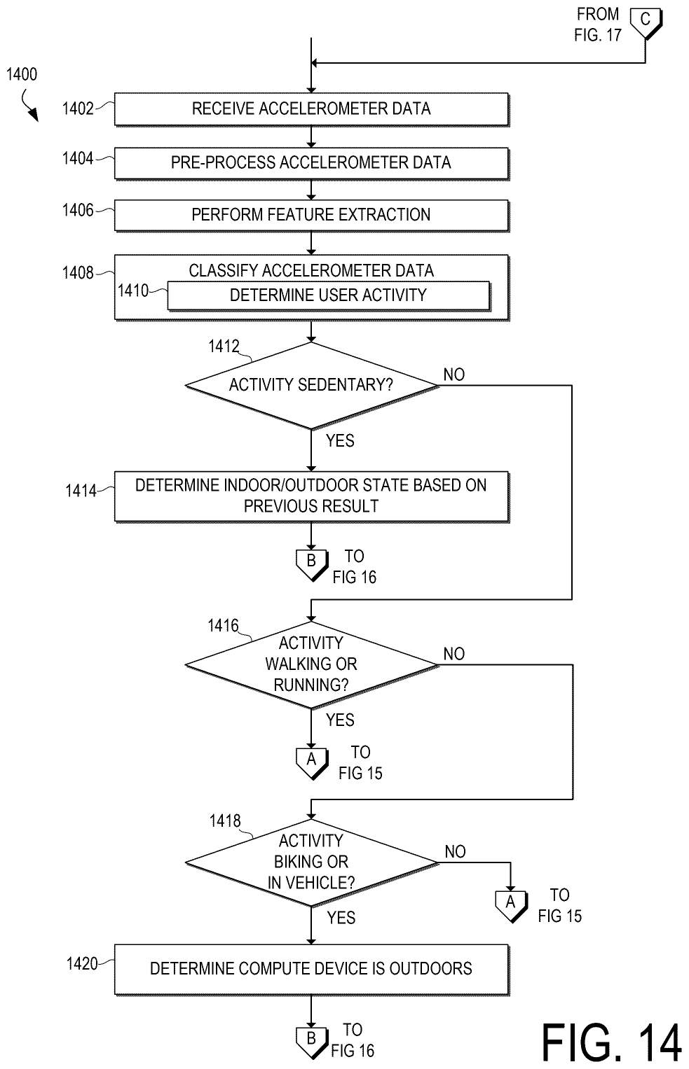

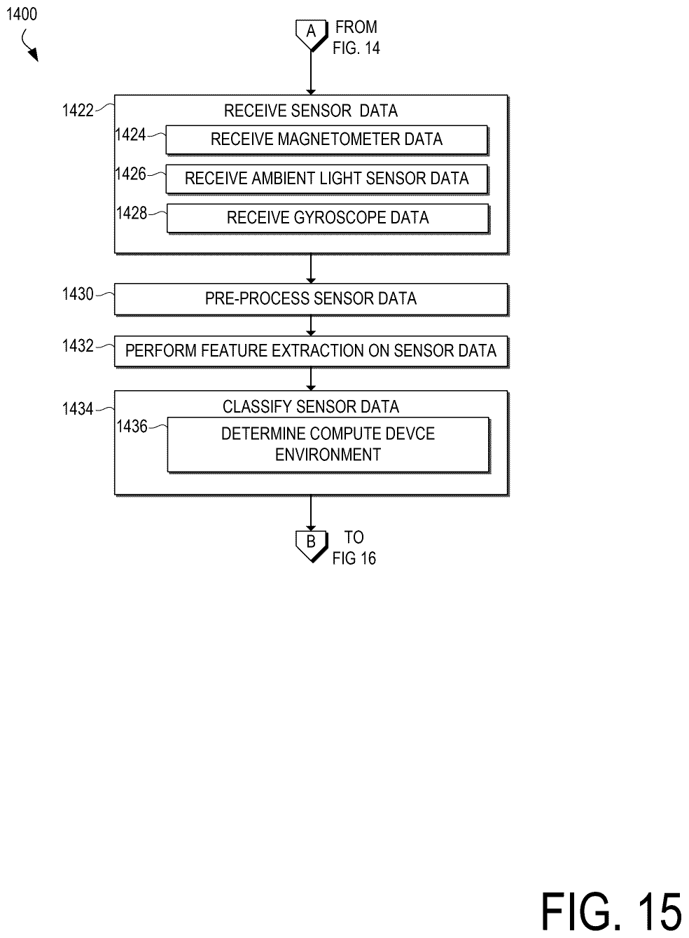

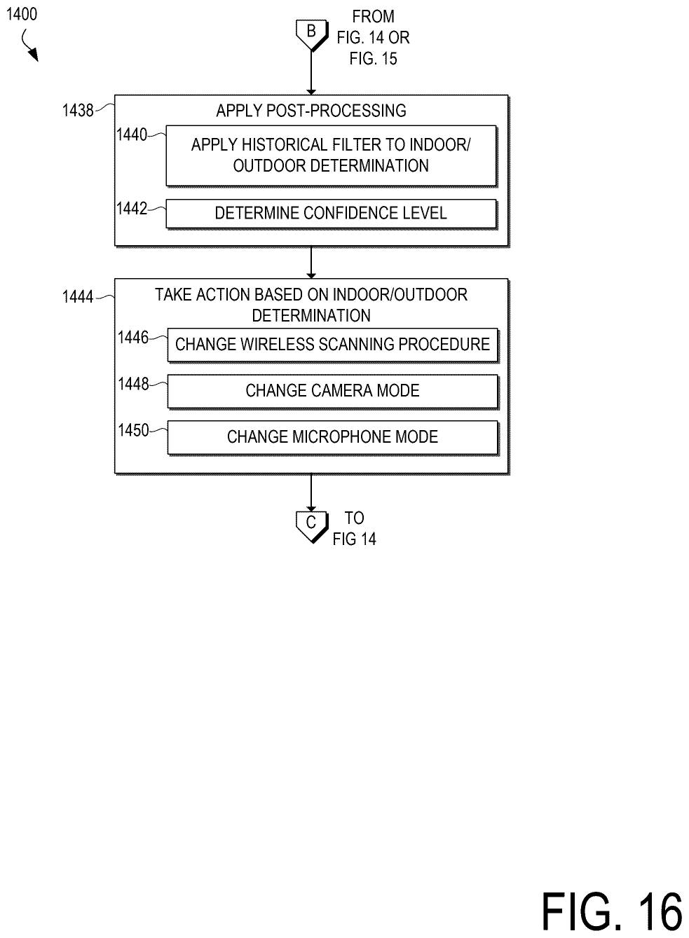

Referring now to FIG. 14, in use, the compute device 100 may execute a method 1400 for determining whether the compute device 100 is indoors or outdoors. The method 1400 begins in block 1402, in which the compute device 100 receives accelerometer data from an accelerometer 116. The compute device 100 may receive accelerometer data in one, two, or three dimensions. The compute device 100 may receive any suitable amount of accelerometer data at any suitable rate. In the illustrative embodiment, the compute device 100 receives one or more frames of accelerometer data, with each frame corresponding to data received at a rate of 50 Hertz for about 5 seconds. The compute device 100 may receive, e.g., 1-10 frames for feature extraction and classification. In other embodiments, the compute device 100 may receive accelerometer data at any suitable rate, such as 10-200 Hz, and for any suitable length of time, such as 1-20 seconds. In block 1404, the compute device 100 preprocesses the accelerometer data.

In block 1406, the compute device 100 performs feature extraction on the accelerometer data. In the illustrative embodiment, the compute device 100 uses 20 sub-band energy features and 20 evenly spaced frequency bands over the spectrum, for a total of 41 features. In other embodiments, the compute device 100 may perform feature extraction in a different manner, such as extracting a different number of features, a different number of frequency bands, etc.

In block 1408, the compute device 100 classifies the accelerometer data. In the illustrative embodiment, the compute device 100 classifies the accelerometer data into one of several possible user activities in block 1410. In the illustrative embodiment, the activities are walking, being sedentary, being in a vehicle, running, biking, fidgeting, and unknown. The illustrative compute device 100 uses a neural network classifier to determine an activity of the user based on the features identified in block 1406. In some embodiments, sensor data from a sensor different from the accelerometer 116 may be used to determine an activity of the user of the compute device 100.

In block 1412, if the identified activity of the user is being sedentary, the method 1400 proceeds to block 1414, in which the compute device 100 determines the indoor/outdoor state based on the previous result. For example, if the compute device 100 had determined that the compute device 100 was inside immediately before receiving and processing the accelerometer data, the compute device 100 may determine that it is still inside. In the illustrative embodiment, the compute device 100 environment monitoring is “always on,” continuously monitoring whether it is indoors or outdoors, so the previous result was determined relatively recently. The method 1400 then proceeds to block 1438 in FIG. 16 to perform any applicable post-processing.

Referring back to block 1412, if the activity is not being sedentary, the method 1400 proceeds to block 1416, in which the compute device 100 determines whether the activity is running or walking. If the activity is running or walking, in the illustrative embodiment, the compute device 100 cannot determine whether the compute device 100 is indoors or outdoors based on the accelerometer data alone. The method 1400 then proceeds to block 1422 in FIG. 15, which the compute device 100 receives additional sensor data. In block 1424, the compute device 100 receives magnetometer data from the magnetometer 120. In block 1426, the compute device 100 receives ambient light data from the ambient light sensor 122. In block 1428, the compute device 100 receives gyroscope data from the gyroscope 118. In the illustrative embodiment, the magnetometer 120, ambient light sensor 122, and/or the gyroscope 118 may not be powered on until the compute device 100 determines that it needs to receive data from the corresponding sensor. In some embodiments, the compute device 100 may not receive data from all of the magnetometer 120, the ambient light sensor 122, and the gyroscope 118.

The compute device may 100 receive any suitable amount of sensor data at any suitable rate. In the illustrative embodiment, the compute device 100 receives one or more frames of sensor data from magnetometer 120, gyroscope 118, and ambient light sensor 122 data, with each frame corresponding to data received at a rate of 10 Hertz for about 5 seconds. The compute device 100 may receive, e.g., 1-10 frames for feature extraction and classification. In other embodiments, the compute device 100 may receive sensor data from any suitable sensor at any suitable rate, such as 1-200 Hz, and for any suitable length of time, such as 1-20 seconds. In block 1430, the compute device 100 preprocesses the sensor data.

In block 1432, the compute device 100 performs feature extraction on the sensor data received in block 1422. Magnetometer data may reflect the effect that metallic objects or electrical appliances have on the Earth's magnetic field, which can be used as fingerprints for indoor detection compared to open spaces outdoors. As the sunlight is the primary source of light in the daytime and the light intensity is typically much higher outdoor than indoor, even on cloudy or rainy days, the ambient light data can be used to help determine whether the compute device 100 is outdoors or indoors. Gyroscope data may be used to help determine whether the compute device 100 is indoors or outdoors as the rotation angle of the compute device 100 may be different indoors and outdoors. For example, a laptop may be held in a hand indoor and placed in a bag outdoors.

In some embodiments, the compute device 100 may use features extracted from the accelerometer data. The features may be used to represent activities besides the six identified above, such as skipping, jogging, going up or down stairs, etc. For example, jogging is likely to be in an open outdoor or semi-outdoor environment, and going up or down stairs is likely to happen in a semi-outdoor or light indoor environment. The accelerometer data may be received in block 1402 or may be received with the rest of the sensor data in block 1422.

In the illustrative embodiment, the compute device 100 extracts time domain and/or frequency features from the sensor data. The features from different sensors may be concatenated into one feature vector per frame. The time domain features may include mean, standard deviation, media, quantiles, range, and mean crossing rate. The frequency domain features may include dominant frequency, spectrum entropy, spectrum roll-off, and 20 sub-band energies. The magnetometer and gyroscope, in some embodiments, the magnitude of the field in computed from a 3-dimensional input, and features are extracted from magnitude only. In other embodiments, features may be extracted using all three dimensions. In the illustrative embodiment, frequency analysis may not be performed on the ambient light data, as the ambient light data does not change as fast as that of the magnetometer and gyroscope. Time domain features extracted from the ambient light sensor may include mean, median, kurtosis (Fisher or Pearson), and range. In total, in the illustrative embodiment, 121 features (including 41 activity features) are extracted per frame.

In block 1434, the compute device 100 classifies the sensor data. In the illustrative embodiment, the compute device 100 classifies the sensor data into one of several possible user environments for the compute device 100 in block 1436. In particular, in the illustrative embodiment, the compute device 100 may classify the sensor data into a deep indoor environment, a light indoor environment, a semi-outdoor environment, and an open outdoor environment.

In the illustrative embodiment, the compute device 100 uses a neural network classifier to determine an environment of the compute device 100. The illustrative neural network is a deep neural network with a 4-layer feed forward network with 57 neurons in the first hidden layer and 30 neurons in the second hidden layer. An input layer has 121 neurons, and the output layer has four classes. A rectified linear unit (ReLU) is used as an activation function. The illustrative DNN uses L2 regularization and a drop layout right before the final output layer. The DNN is trained with an Adam optimizer for 60 iterations with early stopping.

After the compute device 100 has determined an environment of the compute device 100, the method 1400 proceeds to block 1438 in FIG. 16 to apply post-processing.

Referring back to block 1416, in FIG. 14, if the activity is not identified as walking or running, the method 1400 jumps to block 1418, in which the compute device 100 checks if the activity is identified as biking or being in a vehicle. If the activity is identified as biking or being in a vehicle, then the compute device 100 identifies the environment of the compute device as an open outdoors environment in block 1420. The method 1400 then jumps to block 1438 in FIG. 16 to apply any post-processing.

If the activity is not identified as biking or being in a vehicle, then the activity is identified as fidgeting or unknown. In some embodiments, the method 1400 may then proceed to block 1422 in FIG. 15 to receive additional sensor data to determine an environment of the compute device 100. In other embodiments, the method 1400 may loop back to block 1402 to receive one or more additional frames of accelerometer data before possibly proceeding to block 1422 to receive additional sensor data.

Referring now to FIG. 16, in block 1438, after an environment of the compute device 100 is identified, the compute device 100 may apply post-processing. In block 1440, the compute device 100 applies an historical filter, which can help filter out disturbances and improve accuracy. The historical filter can also use switch rules to improve the performance of the indoor/outdoor detection, as shown in FIG. 13. For example, as shown in FIG. 13, the algorithm cannot directly switch from open outdoor 602 to deep indoor 304 (or vice-versa). In block 1442, the compute device 100 may determine a confidence level. For example, if all of the previous, e.g., 10 estimates of the state of the environment are the same, the compute device 100 may have a high confidence. If, for example, the past 10 estimates of the state of the environment have been alternating between light indoor and semi-outdoor, the compute device 100 may have a low confidence.

In block 1444, the compute device 100 may take action based on the determination of whether the compute device 100 is in an indoor environment or an outdoor environment. For example, if the compute device 100 is outdoors (i.e., semi-outdoors or open outdoors), the compute device 100 may change a wireless scanning procedure in block 1446. The compute device 100 may not need to scan channels that cannot be used outside while the compute device 100 is outside, and the compute device 100 may disable transmission on those channels. Conversely, if the compute device 100 is inside (i.e., light inside or deep inside), the compute device 100 may scan all usable channels. In block 1448, the compute device 100 may change a mode of a camera based on a determination of whether the compute device 100 is inside. In block 1450, the compute device 100 may change a mode of a microphone based on a determination of whether the compute device 100 is inside. In some embodiments, the compute device 100 may use the indoor/outdoor environment determination for upper layer applications such as, e.g., healthcare monitoring, tourism, or advertising to recommend personalized products.

### EXAMPLES

Illustrative examples of the technologies disclosed herein are provided below. An embodiment of the technologies may include any one or more, and any combination of, the examples described below.

Example 1 includes a compute device comprising accelerometer data classifier circuitry to determine, based on accelerometer data from an accelerometer of the compute device, a current activity of a user of the compute device; and environment determiner circuitry to determine, based on the current activity, whether the compute device is indoors.

Example 2 includes the subject matter of Example 1, and wherein to determine the current activity of the user comprises to determine that the current activity of the user is biking or riding in a vehicle, wherein to determine, based on the current activity, whether the compute device is indoors comprises to determine that the compute device is outside based on a determination that the current activity of the user is biking or riding in a vehicle.

Example 3 includes the subject matter of any of Examples 1 and 2, and wherein to determine that the compute device is outside based on a determination that the current activity of the user is biking or riding in a vehicle comprises to determine that the compute device is outside based on a determination that the current activity of the user is biking or riding in a vehicle without use of sensor data other than the accelerometer data.

Example 4 includes the subject matter of any of Examples 1-3, and wherein the accelerometer data classifier circuitry is to determine, at a previous time before receipt of the accelerometer data, a previous activity of the user of the compute device, wherein the environment determiner circuitry is to determine, based on the previous activity, whether the compute device is indoors at the previous time, wherein to determine the current activity of the user comprises to determine that the current activity of the user is being sedentary, wherein to determine, in response to a determination that the current activity of the user is being sedentary, whether the compute device is indoors based on a determination of whether the compute device was indoors at the previous time.

Example 5 includes the subject matter of any of Examples 1-4, and wherein to determine the current activity of the user comprises to perform feature extraction on the accelerometer data; and classify the accelerometer data based on the feature extraction and with use of a neural network to determine the current activity of the user.

Example 6 includes the subject matter of any of Examples 1-5, and wherein to determine the current activity of the user comprises to determine that the current activity of the user is walking or running, wherein to determine, based on the current activity, whether the compute device is indoors comprises to receive, in response to a determination that the current activity of the user is walking or running, sensor data from a magnetometer of the compute device, an ambient light sensor of the compute device, or a gyroscope of the compute device; and determine, based on the sensor data, whether the compute device is indoors.

Example 7 includes the subject matter of any of Examples 1-6, and wherein to receive the sensor data from the magnetometer, the ambient light sensor, or the gyroscope comprises to receive sensor data from the magnetometer and sensor data from the ambient light sensor.

Example 8 includes the subject matter of any of Examples 1-7, and wherein to receive the sensor data from the magnetometer, the ambient light sensor, or the gyroscope comprises to receive sensor data from the gyroscope.

Example 9 includes the subject matter of any of Examples 1-8, and wherein the accelerometer, the magnetometer, the ambient light sensor, and the gyroscope are in an integrated sensor hub of the compute device.

Example 10 includes the subject matter of any of Examples 1-9, and wherein to determine whether the compute device is indoors comprises to perform feature extraction on the sensor data from the magnetometer and on the sensor data from the ambient light sensor; and classify the accelerometer data based on the feature extraction and with use of a neural network to determine whether the compute device is indoors.

Example 11 includes the subject matter of any of Examples 1-10, and wherein to determine whether the compute device is indoors comprises to apply a temporal filter to a plurality of determinations of whether the compute device is indoors.

Example 12 includes the subject matter of any of Examples 1-11, and wherein the environment determiner circuitry is further to modify a wireless scanning procedure based on the determination of whether the compute device is indoors.

Example 13 includes the subject matter of any of Examples 1-12, and wherein the environment determiner circuitry is further to change a mode of a camera or a microphone based on the determination of whether the compute device is indoors.

Example 14 includes the subject matter of any of Examples 1-13, and wherein to determine whether the compute device is indoors comprises to determine, by a sensor hub, whether the compute device is indoors with use of less than 5 milliwatts of power.

Example 15 includes a compute device comprising sensor hub controller circuitry to receive accelerometer data from an accelerometer of the compute device; receive magnetometer data from a magnetometer of the compute device; and receive ambient light data from an ambient light sensor of the compute device; and environment determiner circuitry to determine, based on the accelerometer data, the magnetometer data, and the ambient light data, whether the compute device is indoors.

Example 16 includes the subject matter of Example 15, and wherein to determine whether the compute device is indoors comprises to determine whether the compute device is outdoors without use of satellite positioning data.

Example 17 includes the subject matter of any of Examples 15 and 16, and further including accelerometer data classifier to determine that an activity of a user of the compute device is walking or running, wherein to receive the magnetometer data comprises to receive the magnetometer data in response to a determination that the activity of the user is walking or running, wherein to receive the ambient light data comprises to receive the ambient light data in response to a determination that the activity of the user is walking or running.

Example 18 includes a method comprising receiving, by a compute device, accelerometer data from an accelerometer of the compute device; determining, by the compute device and based on the accelerometer data, a current activity of a user of the compute device; and determining, by the compute device and based on the current activity, whether the compute device is indoors.

Example 19 includes the subject matter of Example 18, and wherein determining the current activity of the user comprises determining that the current activity of the user is biking or riding in a vehicle, wherein determining, based on the current activity, whether the compute device is indoors comprises determining that the compute device is outside based on a determination that the current activity of the user is biking or riding in a vehicle.

Example 20 includes the subject matter of any of Examples 18 and 19, and wherein determining that the compute device is outside based on a determination that the current activity of the user is biking or riding in a vehicle comprises determining that the compute device is outside based on a determination that the current activity of the user is biking or riding in a vehicle without use of sensor data other than the accelerometer data.

Example 21 includes the subject matter of any of Examples 18-20, and further including determining, at a previous time before receipt of the accelerometer data, a previous activity of the user of the compute device; and determining, by the compute device and based on the previous activity, whether the compute device is indoors at the previous time, wherein determining the current activity of the user comprises determining that the current activity of the user is being sedentary, wherein determining, by the compute device and in response to a determination that the current activity of the user is being sedentary, whether the compute device is indoors based on a determination of whether the compute device was indoors at the previous time.

Example 22 includes the subject matter of any of Examples 18-21, and wherein determining the current activity of the user comprises performing, by the compute device, feature extraction on the accelerometer data; and classifying, by the compute device, the accelerometer data based on the feature extraction and with use of a neural network to determine the current activity of the user.

Example 23 includes the subject matter of any of Examples 18-22, and wherein determining the current activity of the user comprises determining that the current activity of the user is walking or running, wherein determining, based on the current activity, whether the compute device is indoors comprises receiving, by the compute device and in response to a determination that the current activity of the user is walking or running, sensor data from a magnetometer of the compute device, an ambient light sensor of the compute device, or a gyroscope of the compute device; and determining, by the compute device and based on the sensor data, whether the compute device is indoors.

Example 24 includes the subject matter of any of Examples 18-23, and wherein receiving the sensor data from the magnetometer, the ambient light sensor, or the gyroscope comprises receiving sensor data from the magnetometer and sensor data from the ambient light sensor.

Example 25 includes the subject matter of any of Examples 18-24, and wherein receiving the sensor data from the magnetometer, the ambient light sensor, or the gyroscope comprises receiving sensor data from the gyroscope.

Example 26 includes the subject matter of any of Examples 18-25, and wherein the accelerometer, the magnetometer, the ambient light sensor, and the gyroscope are in an integrated sensor hub of the compute device.

Example 27 includes the subject matter of any of Examples 18-26, and wherein determining whether the compute device is indoors comprises performing, by the compute device, feature extraction on the sensor data from the magnetometer and on the sensor data from the ambient light sensor; and classifying, by the compute device, the accelerometer data based on the feature extraction and with use of a neural network to determine whether the compute device is indoors.

Example 28 includes the subject matter of any of Examples 18-27, and wherein determining whether the compute device is indoors comprises applying a temporal filter to a plurality of determinations of whether the compute device is indoors.

Example 29 includes the subject matter of any of Examples 18-28, and further including modifying, by the compute device, a wireless scanning procedure based on the determination of whether the compute device is indoors.

Example 30 includes the subject matter of any of Examples 18-29, and further including changing, by the compute device, a mode of a camera or a microphone based on the determination of whether the compute device is indoors.

Example 31 includes the subject matter of any of Examples 18-30, and wherein determining whether the compute device is indoors comprises determining, by a sensor hub, whether the compute device is indoors with use of less than 5 milliwatts of power.

Example 32 includes a method comprising receiving, by a compute device, accelerometer data from an accelerometer of the compute device; receiving, by the compute device, magnetometer data from a magnetometer of the compute device; receiving, by the compute device, ambient light data from an ambient light sensor of the compute device; and determining, by the compute device and based on the accelerometer data, the magnetometer data, and the ambient light data, whether the compute device is indoors.

Example 33 includes the subject matter of Example 32, and wherein determining whether the compute device is indoors comprises determining whether the compute device is outdoors without use of satellite positioning data.

Example 34 includes the subject matter of any of Examples 32 and 33, and further including determining, by the compute device, that an activity of a user of the compute device is walking or running, wherein receiving the magnetometer data comprises receiving the magnetometer data in response to a determination that the activity of the user is walking or running, wherein receiving the ambient light data comprises receiving the ambient light data in response to a determination that the activity of the user is walking or running.

Example 35 includes a compute device comprising means for receiving accelerometer data from an accelerometer of the compute device; means for determining, based on the accelerometer data, a current activity of a user of the compute device; and means for determining, based on the current activity, whether the compute device is indoors.

Example 36 includes the subject matter of Example 35, and wherein the means for determining the current activity of the user comprises means for determining that the current activity of the user is biking or riding in a vehicle, wherein the means for determining, based on the current activity, whether the compute device is indoors comprises means for determining that the compute device is outside based on a determination that the current activity of the user is biking or riding in a vehicle.

Example 37 includes the subject matter of any of Examples 35 and 36, and wherein the means for determining that the compute device is outside based on a determination that the current activity of the user is biking or riding in a vehicle comprises means for determining that the compute device is outside based on a determination that the current activity of the user is biking or riding in a vehicle without use of sensor data other than the accelerometer data.

Example 38 includes the subject matter of any of Examples 35-37, and further including means for determining, at a previous time before receipt of the accelerometer data, a previous activity of the user of the compute device; and means for determining, based on the previous activity, whether the compute device is indoors at the previous time, wherein the means for determining the current activity of the user comprises means for determining that the current activity of the user is being sedentary, wherein the means for determining, in response to a determination that the current activity of the user is being sedentary, whether the compute device is indoors based on a determination of whether the compute device was indoors at the previous time.

Example 39 includes the subject matter of any of Examples 35-38, and wherein the means for determining the current activity of the user comprises means for performing feature extraction on the accelerometer data; and means for classifying the accelerometer data based on the feature extraction and with use of a neural network to determine the current activity of the user.

Example 40 includes the subject matter of any of Examples 35-39, and wherein the means for determining the current activity of the user comprises means for determining that the current activity of the user is walking or running, wherein the means for determining, based on the current activity, whether the compute device is indoors comprises means for receiving, in response to a determination that the current activity of the user is walking or running, sensor data from a magnetometer of the compute device, an ambient light sensor of the compute device, or a gyroscope of the compute device; and means for determining, based on the sensor data, whether the compute device is indoors.

Example 41 includes the subject matter of any of Examples 35-40, and wherein the means for receiving the sensor data from the magnetometer, the ambient light sensor, or the gyroscope comprises means for receiving sensor data from the magnetometer and sensor data from the ambient light sensor.

Example 42 includes the subject matter of any of Examples 35-41, and wherein the means for receiving the sensor data from the magnetometer, the ambient light sensor, or the gyroscope comprises means for receiving sensor data from the gyroscope.

Example 43 includes the subject matter of any of Examples 35-42, and wherein the accelerometer, the magnetometer, the ambient light sensor, and the gyroscope are in an integrated sensor hub of the compute device.

Example 44 includes the subject matter of any of Examples 35-43, and wherein the means for determining whether the compute device is indoors comprises means for performing feature extraction on the sensor data from the magnetometer and on the sensor data from the ambient light sensor; and means for classifying the accelerometer data based on the feature extraction and with use of a neural network to determine whether the compute device is indoors.

Example 45 includes the subject matter of any of Examples 35-44, and wherein the means for determining whether the compute device is indoors comprises means for applying a temporal filter to a plurality of determinations of whether the compute device is indoors.

Example 46 includes the subject matter of any of Examples 35-45, and further including means for modifying a wireless scanning procedure based on the determination of whether the compute device is indoors.

Example 47 includes the subject matter of any of Examples 35-46, and further including means for changing a mode of a camera or a microphone based on the determination of whether the compute device is indoors.

Example 48 includes the subject matter of any of Examples 35-47, and wherein the means for determining whether the compute device is indoors comprises means for determining, by a sensor hub, whether the compute device is indoors with use of less than 5 milliwatts of power.

Example 49 includes a compute device comprising means for receiving accelerometer data from an accelerometer of the compute device; means for receiving magnetometer data from a magnetometer of the compute device; means for receiving ambient light data from an ambient light sensor of the compute device; and means for determining, based on the accelerometer data, the magnetometer data, and the ambient light data, whether the compute device is indoors.

Example 50 includes the subject matter of Example 49, and wherein the means for determining whether the compute device is indoors comprises means for determining whether the compute device is outdoors without use of satellite positioning data.

Example 51 includes the subject matter of any of Examples 49 and 50, and further including means for determining that an activity of a user of the compute device is walking or running, wherein the means for receiving the magnetometer data comprises means for receiving the magnetometer data in response to a determination that the activity of the user is walking or running, wherein the means for receiving the ambient light data comprises means for receiving the ambient light data in response to a determination that the activity of the user is walking or running.

Example 52 includes one or more computer-readable media comprising a plurality of instructions stored thereon that, when executed, causes a compute device to determine, based on accelerometer data from an accelerometer of the compute device, a current activity of a user of the compute device; and determine, based on the current activity, whether the compute device is indoors.

Example 53 includes the subject matter of Example 52, and wherein to determine the current activity of the user comprises to determine that the current activity of the user is biking or riding in a vehicle, wherein to determine, based on the current activity, whether the compute device is indoors comprises to determine that the compute device is outside based on a determination that the current activity of the user is biking or riding in a vehicle.

Example 54 includes the subject matter of any of Examples 52 and 53, and wherein to determine that the compute device is outside based on a determination that the current activity of the user is biking or riding in a vehicle comprises to determine that the compute device is outside based on a determination that the current activity of the user is biking or riding in a vehicle without use of sensor data other than the accelerometer data.

Example 55 includes the subject matter of any of Examples 52-54, and wherein the plurality of instructions further cause the compute device to determine, at a previous time before receipt of the accelerometer data, a previous activity of the user of the compute device, determine, based on the previous activity, whether the compute device is indoors at the previous time, wherein to determine the current activity of the user comprises to determine that the current activity of the user is being sedentary, wherein to determine, in response to a determination that the current activity of the user is being sedentary, whether the compute device is indoors based on a determination of whether the compute device was indoors at the previous time.

Example 56 includes the subject matter of any of Examples 52-55, and wherein to determine the current activity of the user comprises to perform feature extraction on the accelerometer data; and classify the accelerometer data based on the feature extraction and with use of a neural network to determine the current activity of the user.

Example 57 includes the subject matter of any of Examples 52-56, and wherein to determine the current activity of the user comprises to determine that the current activity of the user is walking or running, wherein to determine, based on the current activity, whether the compute device is indoors comprises to receive, in response to a determination that the current activity of the user is walking or running, sensor data from a magnetometer of the compute device, an ambient light sensor of the compute device, or a gyroscope of the compute device; and determine, based on the sensor data, whether the compute device is indoors.

Example 58 includes the subject matter of any of Examples 52-57, and wherein to receive the sensor data from the magnetometer, the ambient light sensor, or the gyroscope comprises to receive sensor data from the magnetometer and sensor data from the ambient light sensor.

Example 59 includes the subject matter of any of Examples 52-58, and wherein to receive the sensor data from the magnetometer, the ambient light sensor, or the gyroscope comprises to receive sensor data from the gyroscope.

Example 60 includes the subject matter of any of Examples 52-59, and wherein the accelerometer, the magnetometer, the ambient light sensor, and the gyroscope are in an integrated sensor hub of the compute device.

Example 61 includes the subject matter of any of Examples 52-60, and wherein to determine whether the compute device is indoors comprises to perform feature extraction on the sensor data from the magnetometer and on the sensor data from the ambient light sensor; and classify the accelerometer data based on the feature extraction and with use of a neural network to determine whether the compute device is indoors.

Example 62 includes the subject matter of any of Examples 52-61, and wherein to determine whether the compute device is indoors comprises to apply a temporal filter to a plurality of determinations of whether the compute device is indoors.

Example 63 includes the subject matter of any of Examples 52-62, and wherein the plurality of instructions further causes the compute device to modify a wireless scanning procedure based on the determination of whether the compute device is indoors.

Example 64 includes the subject matter of any of Examples 52-63, and wherein the plurality of instructions further causes the compute device to change a mode of a camera or a microphone based on the determination of whether the compute device is indoors.

Example 65 includes the subject matter of any of Examples 52-64, and wherein to determine whether the compute device is indoors comprises to determine, by a sensor hub, whether the compute device is indoors with use of less than 5 milliwatts of power.

Example 66 includes one or more computer-readable media comprising a plurality of instructions stored thereon that, when executed, causes a compute device to receive accelerometer data from an accelerometer of the compute device; receive magnetometer data from a magnetometer of the compute device; and receive ambient light data from an ambient light sensor of the compute device; and determine, based on the accelerometer data, the magnetometer data, and the ambient light data, whether the compute device is indoors.

Example 67 includes the subject matter of Example 66, and wherein to determine whether the compute device is indoors comprises to determine whether the compute device is outdoors without use of satellite positioning data.

Example 68 includes the subject matter of any of Examples 66 and 67, and wherein the plurality of instructions further cause the compute device to determine that an activity of a user of the compute device is walking or running, wherein to receive the magnetometer data comprises to receive the magnetometer data in response to a determination that the activity of the user is walking or running, wherein to receive the ambient light data comprises to receive the ambient light data in response to a determination that the activity of the user is walking or running.

1-25. (canceled)

26. A compute device comprising:
accelerometer data classifier circuitry to determine, based on accelerometer data from an accelerometer of the compute device, a current activity of a user of the compute device; and
environment determiner circuitry to determine, based on the current activity, whether the compute device is indoors.

27. The compute device of claim 26,
wherein to determine the current activity of the user comprises to determine that the current activity of the user is biking or riding in a vehicle,
wherein to determine, based on the current activity, whether the compute device is indoors comprises to determine that the compute device is outside based on a determination that the current activity of the user is biking or riding in a vehicle.

28. The compute device of claim 27,
wherein to determine that the compute device is outside based on a determination that the current activity of the user is biking or riding in a vehicle comprises to determine that the compute device is outside based on a determination that the current activity of the user is biking or riding in a vehicle without use of sensor data other than the accelerometer data.

29. The compute device of claim 26, wherein the accelerometer data classifier circuitry is to determine, at a previous time before receipt of the accelerometer data, a previous activity of the user of the compute device,
wherein the environment determiner circuitry is to determine, based on the previous activity, whether the compute device is indoors at the previous time,
wherein to determine the current activity of the user comprises to determine that the current activity of the user is being sedentary,
wherein to determine, in response to a determination that the current activity of the user is being sedentary, whether the compute device is indoors based on a determination of whether the compute device was indoors at the previous time.

30. The compute device of claim 26, wherein to determine the current activity of the user comprises to:
perform feature extraction on the accelerometer data; and
classify the accelerometer data based on the feature extraction and with use of a neural network to determine the current activity of the user.

31. The compute device of claim 26,
wherein to determine the current activity of the user comprises to determine that the current activity of the user is walking or running,
wherein to determine, based on the current activity, whether the compute device is indoors comprises to:
receive, in response to a determination that the current activity of the user is walking or running, sensor data from a magnetometer of the compute device, an ambient light sensor of the compute device, or a gyroscope of the compute device; and
determine, based on the sensor data, whether the compute device is indoors.

32. The compute device of claim 31, wherein to receive the sensor data from the magnetometer, the ambient light sensor, or the gyroscope comprises to receive sensor data from the magnetometer and sensor data from the ambient light sensor.

33. The compute device of claim 31, wherein to receive the sensor data from the magnetometer, the ambient light sensor, or the gyroscope comprises to receive sensor data from the gyroscope.

34. The compute device of claim 31, wherein the accelerometer, the magnetometer, the ambient light sensor, and the gyroscope are in an integrated sensor hub of the compute device.

35. The compute device of claim 31, wherein to determine whether the compute device is indoors comprises to:
perform feature extraction on the sensor data from the magnetometer and on the sensor data from the ambient light sensor; and
classify the accelerometer data based on the feature extraction and with use of a neural network to determine whether the compute device is indoors.

36. The compute device of claim 35, wherein to determine whether the compute device is indoors comprises to apply a temporal filter to a plurality of determinations of whether the compute device is indoors.

37. The compute device of claim 26, wherein the environment determiner circuitry is further to modify a wireless scanning procedure based on the determination of whether the compute device is indoors.

38. The compute device of claim 26, wherein the environment determiner circuitry is further to change a mode of a camera or a microphone based on the determination of whether the compute device is indoors.

39. The compute device of claim 26, wherein to determine whether the compute device is indoors comprises to determine, by a sensor hub, whether the compute device is indoors with use of less than 5 milliwatts of power.

40. A compute device comprising:
sensor hub controller circuitry to:
receive accelerometer data from an accelerometer of the compute device;
receive magnetometer data from a magnetometer of the compute device; and
receive ambient light data from an ambient light sensor of the compute device; and
environment determiner circuitry to determine, based on the accelerometer data, the magnetometer data, and the ambient light data, whether the compute device is indoors.

41. The compute device of claim 40, wherein to determine whether the compute device is indoors comprises to determine whether the compute device is outdoors without use of satellite positioning data.

42. The compute device of claim 40, further comprising accelerometer data classifier to determine that an activity of a user of the compute device is walking or running,
wherein to receive the magnetometer data comprises to receive the magnetometer data in response to a determination that the activity of the user is walking or running,
wherein to receive the ambient light data comprises to receive the ambient light data in response to a determination that the activity of the user is walking or running.

43. A compute device comprising:
means for receiving accelerometer data from an accelerometer of the compute device;
means for determining, based on the accelerometer data, a current activity of a user of the compute device; and
means for determining, based on the current activity, whether the compute device is indoors.

44. The compute device of claim 43,
wherein the means for determining the current activity of the user comprises means for determining that the current activity of the user is walking or running,
wherein the means for determining, based on the current activity, whether the compute device is indoors comprises:
means for receiving, in response to a determination that the current activity of the user is walking or running, sensor data from a magnetometer of the compute device, an ambient light sensor of the compute device, or a gyroscope of the compute device; and
means for determining, based on the sensor data, whether the compute device is indoors.

45. The compute device of claim 43, further comprising:
means for determining, at a previous time before receipt of the accelerometer data, a previous activity of the user of the compute device; and
means for determining, based on the previous activity, whether the compute device is indoors at the previous time,
wherein the means for determining the current activity of the user comprises means for determining that the current activity of the user is being sedentary,
wherein the means for determining, in response to a determination that the current activity of the user is being sedentary, whether the compute device is indoors based on a determination of whether the compute device was indoors at the previous time.
